(19) United States
(12) Patent Application Publication
(10) Pub. No.: US 2026/0064925 A1
(43) Pub. Date: Mar. 5, 2026

(54) SUBSTRATE PROCESS DATA LABELING

(71) Applicant: Applied Materials, Inc., Santa Clara, CA (US)

(72) Inventors: Bharath Ram Sundar, Chennai (IN); Raman Nurani, Chennai (IN); Ramaswamy Melatoor Narayanan, Chennai (IN); Ganapathi Raman Sankaranarayanan, Chennai (IN); Ramachandran Subramanian, Chennai (IN); Regina Freed, Los Altos, CA (US); Yi-Chuan Chou, Fremont, CA (US); Anandaraman Vithyananthan, Tamil Nadu (IN); Rajaraman Subramanian, Tamilnadu (IN); Jagadeesh Govindaraj, Chennai (IN); Mareeswaran Sooriamoorthy, Tamil Nadu (IN); Aditi Gupta, Hayward, CA (US)

(21) Appl. No.: 18/823,056

(22) Filed: Sep. 3, 2024

(51) Int. Cl. G06F 30/327; G06F 30/31

(52) U.S. Cl. CPC G06F 30/327; G06F 30/31

(57) ABSTRACT

A method includes obtaining a first plurality of data entries comprising process data of one or more processes performed on a plurality of substrates. The method further includes determining an operation of interest from the first plurality of data entries. The method further includes updating a first subset of data entries of the first plurality of data entries by normalizing the operation of interest across the first plurality of data entries. The method further includes labeling the first subset of data entries with a common label. The method further includes obtaining a second plurality of data entries comprising metrology data. The method further includes linking the process data of the updated first subset of data entries to the metrology data. The method further includes preparing the updated first subset of data entries for one or more data analysis operations based on the common label.

### TECHNICAL FIELD

The present disclosure relates data labeling, and more specifically the present disclosure relates to substrate process data labeling.

### BACKGROUND

Products may be produced by performing one or more manufacturing processes using manufacturing equipment. For example, semiconductor manufacturing equipment may be used to process substrates and produce electronic devices (e.g., chips) via semiconductor manufacturing processes. Products are to be produced with particular properties, suited for a target application. Understanding and controlling properties within the manufacturing chamber aids in consistent production of products. Connections between substrate generation parameters and substrate properties may be exploited for design or improvement of substrate generation procedures.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular embodiments of the disclosure or any scope of the claims. Its sole purpose is to present some concepts of the disclosure in a simplified form as a prelude to the more detailed description that is presented later.

In one aspect of the present disclosure, a method includes obtaining, by a processing device, a first plurality of data entries comprising process data of one or more processes performed on a plurality of substrates. Each data entry of the first plurality of data entries includes process data for a plurality of operations of the one or more processes. One or more first data entries of the first plurality of data entries has at least one of a different operation mapping or different operation names than one or more second data entries of the first plurality of data entries. The method further includes determining an operation of interest from the first plurality of data entries. For the one or more first data entries the operation of interest has at least a first operation mapping in the one or more processes or a first operation name. For the one or more second data entries the operation of interest has at least one of a second operation mapping in the one or more processes or a second operation name. The method further includes updating at least a first subset of data entries of the first plurality of data entries by normalizing the operation of interest across the first plurality of data entries. The method further includes labeling at least the first subset of data entries with a common label associated with the normalized operation of interest. The method further includes obtaining, by the processing device, a second plurality of data entries including metrology data of the plurality of substrates. The method further includes linking the process data of the updated first subset of data entries of the first plurality of data entries to the metrology data of the second plurality of data entries. The method further includes preparing, by the processing device, the updated first subset of data entries for one or more data analysis operations based at least in part on the common label.

In another aspect of the present disclosure, a system includes a memory and a processing device operatively coupled to the memory. The processing device is configured to obtain a first plurality of data entries including process data of one or more processes performed on a plurality of substrates. Each data entry of the first plurality of data entries includes process data for a plurality of operations of the one or more processes. One or more first data entries of the first plurality of data entries has at least one of a different operation mapping or different operation names than one or more second data entries of the first plurality of data entries. The processing device is further configured to determine an operation of interest from the first plurality of data entries. For the one or more first data entries the operation of interest has at least a first operation mapping in the one or more processes or a first operation name. For the one or more second data entries the operation of interest has at least one of a second operation mapping in the one or more processes or a second operation name. The processing device is further configured to update at least a first subset of data entries of the first plurality of data entries by normalizing the operation of interest across the first plurality of data entries. The processing device is further configured to label at least the first subset of data entries with a common label associated with the normalized operation of interest. The processing device is further configured to obtain a second plurality of data entries including metrology data of the plurality of substrates. The processing device is further configured to link the process data of the updated first subset of data entries of the first plurality of data entries to the metrology data of the second plurality of data entries. The processing device is further configured to prepare the updated first subset of data entries for one or more data analysis operations based at least in part on the common label.

In a further aspect of the present disclosure, a non-transitory machine-readable storage medium stores instructions which, when executed, cause a processing device to perform operations. The operations include obtaining a first plurality of data entries including process data of one or more processes performed on a plurality of substrates. Each data entry of the first plurality of data entries includes process data for a plurality of operations of the one or more processes. One or more first data entries of the first plurality of data entries has at least one of a different operation mapping or different operation names than one or more second data entries of the first plurality of data entries. The operations further include determining an operation of interest from the first plurality of data entries. For the one or more first data entries the operation of interest has at least a first operation mapping in the one or more processes or a first operation name. For the one or more second data entries the operation of interest has at least one of a second operation mapping in the one or more processes or a second operation name. The operations further include updating at least a first subset of data entries of the first plurality of data entries by normalizing the operation of interest across the first plurality of data entries. The operations further include labeling at least the first subset of data entries with a common label associated with the normalized operation of interest. The operations further include obtaining a second plurality of data entries including metrology data of the plurality of substrates. The operations further include linking the process data of the updated first subset of data entries of the first plurality of data entries to the metrology data of the second plurality of data entries. The operations further include preparing the updated first subset of data entries for one or more data analysis operations based at least in part on the common label.

### BRIEF DESCRIPTION OF THE DRAWINGS

The present disclosure is illustrated by way of example, and not by way of limitation in the figures of the accompanying drawings.

FIG. 1 is a block diagram illustrating an exemplary system architecture, according to some embodiments of the present disclosure.

FIG. 2 depicts an exemplary data flow for labeling substrate process data, according to some embodiments.

FIGS. 3A-C depict exemplary data mapping for substrate process data, according to some embodiments.

FIGS. 4A-B depict example user interface (UI) elements, according to some embodiments.

FIG. 5 is a block diagram illustrating a method for training and using a machine learning model, according to some embodiments.

FIG. 6 is a flow diagram of a method for labeling substrate process data, according to some embodiments.

FIG. 7 is a block diagram illustrating a computer system, according to some embodiments.

### DETAILED DESCRIPTION

Described herein are technologies related to substrate process data labeling, such as for substrates processed using manufacturing equipment, etc. Data analysis, training of machine learning models, etc. can be performed using the data labeled according to embodiments described herein.

Manufacturing equipment may be used to produce products, such as electronic devices formed on substrates (e.g., wafers). For example, semiconductor devices, displays, photovoltaics, etc. may be manufactured using a sequence of processes. Manufacturing equipment (e.g., manufacturing tools) often includes a processing chamber that separates the substrate being processed from the environment. The properties of produced substrates are to meet target property values to facilitate performance, functionality, etc. Anomalies, drift, or other differences in processing environment may generate substrates with sub-optimal performance, e.g., semiconductors that fail to function as intended. Additionally, such anomalies, drift and/or other differences may introduce inefficiencies in manufacturing (for example, additional expenditure of time, materials, energy, etc.). A processing environment may be quantified by various sensors associated with a processing chamber, e.g., pressure gauges, temperatures sensors, sensors indicative of electrical power (e.g., voltmeters, etc.), gas flow meters, etc. Manufacturing equipment may be used to generate physical substrates.

During development of process recipes, large quantities of data are collected. The data may be collected during test process runs, etc. Such data can be associated with process setpoints, measured sensor values, and/or substrate metrology. Conventionally, the data collected is manually labeled by users such as engineers or technicians, etc. Additionally, after development of process recipes, data may be collected on product substrates that are processed according to those recipes. Consistent data labeling conventions may not be used by the users. For example, a first user may give a first name to a dataset associated with a process operation while a second user may give a different second name to another dataset associated with the same process operation. The same situation may occur with respect to metrology data and/or sensor data, etc. For example, different names may be applied to the same metrology measurement and/or to the same sensor measurement across different data sets. When data sets are not named using a consistent naming convention, identifying a process operation of interest from the data sets, and therefore performing meaningful analysis on all the collected data sets, can be difficult. In another example, a set of process data for a substrate process may represent multiple sub-processes in a single dataset, while another set of process data for the same substrate process may include multiple subsets of data to represent each of the sub-processes. Therefore, collected datasets for the substrate process having multiple sub-processes may not map to one another. When datasets for substrate processes and/or sub-processes are not properly mapped to one another, meaningful data analysis can be difficult if not impossible. In some embodiments described herein, a method for labeling substrate process data in bulk with a common label that normalizes sets of data is provided. The normalized sets of data can be used for data analysis and/or for training a machine learning model, etc. In some embodiments, data may be normalized across different naming and/or across different step mappings of a process. In some embodiments, data may be normalized across different naming of a process operation for multiple processes. For example, the data may be normalized for different names of a corresponding process operation for multiple different processes.

Embodiments described herein provide a software tool that enables bulk curation and labeling of data from local semantic labels and machine generated context. A local semantic label may be a label assigned by a user. The local semantic label may be comprised of natural language and/or abbreviated language. The local semantic label may not be in a standardized format. In some embodiments, the software tool enables bulk curation and labeling of data associated with substrate processing operations and/or substrate process recipes, etc. The software tool described herein enables process operation mapping, chamber sensor mapping, metrology type mapping, and/or data visualization tools deriving insights from the above. The software tool described herein enables the performance of data mining and/or data analysis at a large scale. In some embodiments, machine learning models are trained based on the data sets labeled as described herein.

As substrates are processed, data is collected. A first plurality of data entries is obtained, such as by a processing device. The first plurality of data entries includes process data of one or more processes performed on a plurality of substrates. Each data entry includes process data for a plurality of process operations. Process data may include process setpoints (e.g., such as power setpoints, temperature setpoints, gas flow setpoints, etc.), process knob settings, process duration, and/or sensor measurements, etc. Process data may include sensor data, recipe data, and/or manufacturing parameters, etc. One or more first data entries of the first plurality of data entries has a different operation mapping and/or different operation names than one or more second data entries of the first plurality of data entries. As used herein, an operation mapping corresponds to where an operation is positioned in a process recipe (e.g., whether the operation is a first step, a second step, a third step, etc. of a recipe). The same process operation may have different operation mappings for different data sets. For example, an operation may be a fifth operation in a first data set and may be a sixth operation in a second data set, etc. Each of the data sets may correspond to the process operation executed at a different time and/or using a different process tool, etc.

In some embodiments, an operation of interest is determined from the first plurality of data entries. An operation of interest may be a process operation (e.g., a process step, etc.) or a process sub-operation. In some embodiments, a user provides input, via a user interface (UI) element, indicating which process operation is the operation of interest. The user may provide the input, for example, by typing an operation name or part of an operation name into a text entry field of a UI. Alternatively, or additionally, the user may select an operation from a dropdown menu of available operations. In some embodiments, the UI displays a list of data entries. Once an operation of interest is selected, the displayed data entries may be reduced by excluding those data entries that do not include the selected operation. In some embodiments, an operation of interest may be selected by selecting on an instance of that operation in a displayed data entry that includes that operation.

In some embodiments, for the one or more first data entries, the operation of interest has a first operation mapping in the one or more processes, and/or the operation of interest has a first operation name in the one or more processes. For the one or more second data entries, the operation of interest may have a second operation mapping in the one or more processes (e.g., different from the first operation mapping), and/or the operation of interest may have a second operation name in the one or more processes. For example, and in some embodiments, the operation of interest has a mapping or naming convention that is different between the first data entries and the second data entries.

Once the operation of interest is determined, at least a first subset of data entries of the first plurality of data entries is updated by normalizing the operation of interest across the first plurality of data entries. For example, and in some embodiments, data entries of the first plurality of data entries are identified as corresponding to one another (e.g., the data entries represent the same process operation or sub-operation, etc.). Data entries which correspond to the same process operation (e.g., or sub-operation) may be identified. The identified data entries are labeled with a common label associated with the normalized operation of interest. The common label may be a name corresponding to the operation of interest. In some embodiments, the first subset of data entries are labeled with the common label. The common label may be to quickly and easily identify the normalized operation of interest, such as for data operations and/or analysis, etc. In some embodiments, the common label is input by a user. Alternatively, the common label may automatically be determined based on the current labels of the identified instances of the operation in the data entries. For example, processing logic may determine a most used label for the operation of interest across the data entries, and may automatically select that label for use of the common label. The initial labels of the data entries for the operation of interest may be replaced by the common label in some embodiments. Alternatively, a new common label may be added to the data entries without change to the original labels for the operation in the data entries.

In embodiments, one or more sensor measurements may be associated with the operation of interest. Examples of sensor measurements include temperature measurements, pressure measurements, power measurements, gas flow rates, and so on. The measurements may include raw measurements and/or statistical calculations generated from raw measurements, such as averages, medians, maximums, minimums, and so on. Sensor names and/or sensor measurement names may differ across data entries. In some embodiments, processing logic may select (optionally based on user input) a sensor or sensor measurement of interest. Processing logic may determine (optionally based on user input) a common label (e.g., sensor name or sensor measurement name) to apply to the sensor measurements, and may then apply the common label to the sensor measurements of the data entries in embodiments.

As the substrates are processed or after the substrates are processed, metrology data is collected. A second plurality of data entries is obtained, such as by the processing device. The second plurality of data entries includes metrology data of the plurality of substrates. The metrology data may include measurements of the processed substrates, such as feature size and/or substrate dimension measurements, etc. The process data (e.g., labeled with the common label) is linked with the metrology data of the second plurality of data entries. Once the data is linked, the first subset of data entries (e.g., labeled with the common label) is prepared, such as by the processing device, for one or more data analysis operations based at least in part on the common label for the operation.

In some embodiments, different names may be used for the same metrology measurements across the second plurality of data entries. In some embodiments, processing logic may select (optionally based on user input) a metrology measurement of interest. Processing logic may determine (optionally based on user input) a common label (e.g., metrology name) to apply to the metrology measurements, and may then apply the common label to the metrology measurements of one or more of the second plurality of data entries in embodiments.

In some embodiments, the updated first subset of data entries and/or a subset of the second plurality of data entries is prepared for data mining operations and/or for training a machine learning model. Updates to the operation of interest may be performed based on the data mining and/or one or more outputs of a trained machine learning model.

Embodiments of the present disclosure provide advantages, such as labeling process data in bulk so that effective data analysis can be performed quickly and efficiently. The embodiments described herein allow for a user to quickly label large amounts of corresponding data with a common label (e.g., a common name). Once labeled, the data can be quickly and easily identified, such as for performing data analysis and/or for training a machine learning model. Output(s) from the data analysis and/or from the trained machine learning model can be used to update process recipes, etc. Embodiments described herein can more quickly label process data than conventional methods which are largely performed manually. A computer-aided method of labeling process data, such as the methods described herein, can shorten the amount of time a user spends labeling data in anticipation of data analysis and/or training a machine learning model with the labeled data.

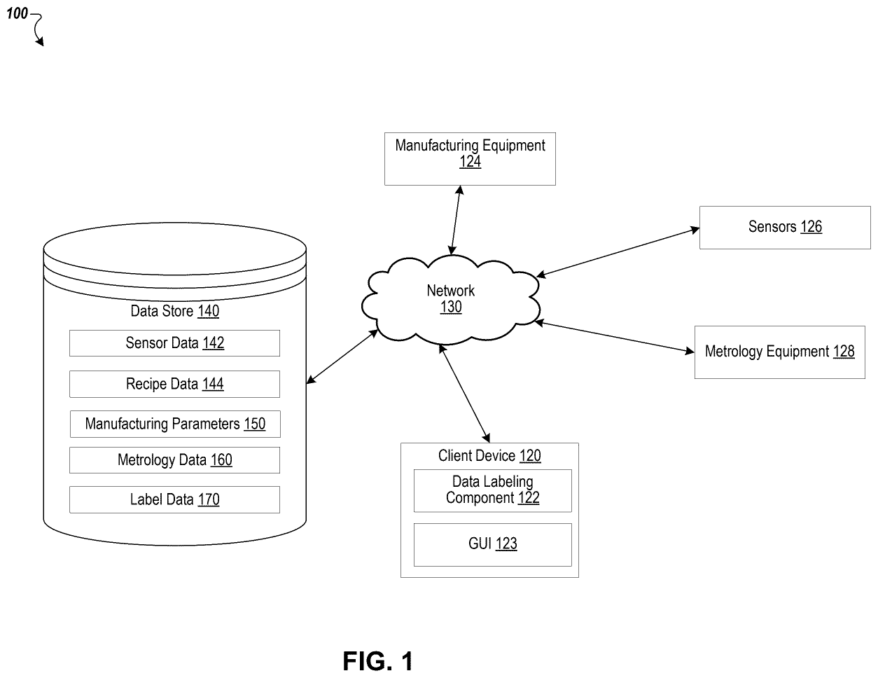

FIG. 1 is a block diagram illustrating an exemplary system 100 (exemplary system architecture), according to some embodiments. The system 100 includes a client device 120, manufacturing equipment 124, sensors 126, metrology equipment 128, and data store 140.

Sensors 126 may provide sensor data 142 associated with manufacturing equipment 124 (e.g., associated with producing, by manufacturing equipment 124, corresponding products, such as substrates). Sensor data 142 may be included in a set of processed substrate data. Sensor data 142 may be used to ascertain equipment health and/or product health (e.g., product quality). Manufacturing equipment 124 may produce products following a recipe or performing runs over a period of time. In some embodiments, sensor data 142 may include values of one or more of optical sensor data, spectral data, temperature (e.g., heater temperature), spacing (SP), pressure, High Frequency Radio Frequency (HFRF), radio frequency (RF) match voltage, RF match current, RF match capacitor position, voltage of Electrostatic Chuck (ESC), actuator position, electrical current, flow, power, voltage, etc. Sensor data (e.g., a portion of the sensor data 142) may be associated with a product currently being processed, a product recently processed, a number of recently processed products, etc. Sensor data may include data stored associated with previously produced products. Sensor data 142 may include attribute data, label of a state of manufacturing equipment, etc. Examples of attribute data include labels of manufacturing equipment ID or design, sensor ID, type, and/or location. Examples of labels of a state of manufacturing equipment include a present fault, a service lifetime, and so on.

In some embodiments, the recipe data 144 include parameters of processes performed by components of the manufacturing equipment 124 (e.g., etching, heating, cooling, transferring, processing, flowing, cleaning, etc.). Recipe data 144 may be included in a set of processed substrate data. In some embodiments, recipe data 144 may include one or more of transfer operation data, processing operation data, cleaning operation data, and/or the like. In some embodiments, at least a portion of the recipe data 144 is from client device 120, data store 140, and/or sensors 126. In some embodiments, the recipe data 144 includes sequences of operations, and set points associated with each of the operations. In some embodiments, the operations may include transfer operations, processing operations, etc. Processed recipe data (e.g., processed transfer data, processed processing data), pattern in the recipe data 144 (e.g., repetition of transfers, processing, etc.), or a combination of values from the recipe data 144 (e.g., ratio of transfer time to processing time, etc.) may be stored for each instance of a recipe that has been run on a substrate in embodiments.

Sensor data 142 may be associated with, correlated to, and/or indicative of sensor measurements made during processing of substrates. Such sensor measurements may include temperature sensor measurements, gas flow sensor measurements, etc.

Data associated with some hardware parameters and/or process parameters may, instead or additionally, be stored as manufacturing parameters 150. Examples of hardware parameters include hardware settings or installed components, such as size, type, etc. of installed components. Examples of process parameters include heater settings, gas flow settings, pressure settings, and so on. The manufacturing parameters 150 may include historical manufacturing parameters (e.g., associated with historical processing runs) and current manufacturing parameters. Manufacturing parameters 150 may be indicative of input settings to the manufacturing device (e.g., heater power, gas flow, etc.). Manufacturing parameters 150 may be included in a set of processed substrate data.

Sensor data 142 and/or manufacturing parameters 150 may be provided while the manufacturing equipment 124 is performing manufacturing processes (e.g., equipment readings while processing products), and may be stored thereafter. Sensor data 142 may be different for each product (e.g., each substrate).

Substrates may have property values measured by metrology equipment 128. Examples of property values include film thickness, film strain, critical dimensions, optical properties, electrical properties, etc. The property values may be measured at a standalone metrology facility, measured by an integrated or inline metrology system, or the like. Metrology data 160 may be stored in data store 140. Metrology data 160 may include historical metrology data (e.g., metrology data associated with previously processed products). Metrology data 160 may be included in a set of processed substrate data.

In some embodiments, metrology data 160 may be provided without use of a standalone metrology facility. For example, metrology data 160 may be in-situ metrology data (e.g., metrology or a proxy for metrology collected during processing), integrated metrology data (e.g., metrology or a proxy for metrology collected while a product is within a chamber or under vacuum, but not during processing operations), inline metrology data (e.g., data collected after a substrate is removed from vacuum), etc. In some embodiments, metrology data 160 corresponds to historical property data of products. Historical property data of products may include data for products processed using manufacturing parameters associated with historical sensor data, historical recipes, and/or historical manufacturing parameters.

Metrology equipment 128 may include microscopy and/or imaging equipment in some embodiments. Metrology equipment 128 may include one or more devices for obtaining an image of a substrate, of a portion of a substrate, of features of a substrate, or the like. Metrology equipment 128 may include SEM equipment, XSEM equipment, TEM equipment, and/or other forms of imaging and/or microscopy equipment. Metrology data 160 may include image data, microscopy data, and the like.

Each instance (e.g., set) of sensor data 142 may correspond to a product (e.g., a substrate), a set of manufacturing equipment, a type of substrate produced by manufacturing equipment, or the like. Each instance of metrology data 160 and manufacturing parameters 150 may likewise correspond to a product, a set of manufacturing equipment, a type of substrate produced by manufacturing equipment, or the like. The data store may further store information associating sets of different data types, e.g. information indicative that a set of sensor data, a set of metrology data, and a set of manufacturing parameters are all associated with the same product, manufacturing equipment, type of substrate, etc.

Label data 170 may include name data and/or mapping data for the sensor data 142, the recipe data 144, manufacturing parameters 150, and/or metrology data 160. The label data 170 may include one or more common labels that identify one or more common parameters associated with instances of the sensor data 142, the recipe data 144, the manufacturing parameters 150, and/or the metrology data 160. The common labels may include a name label (e.g., such as a name of a process operation or a name of a sensor, etc.) or a mapping label (e.g., such as a mapping of one or more associated process operations, etc.). In some embodiments, the label data 170 is generated based on user input received at the client device 120 via the graphical user interface (GUI) 123. For example, and in some embodiments, a user may enter and/or select a name label and/or a mapping label via an element of the GUI 123. Data associated with the name label and/or mapping label may be generated and stored in the data store 140.

Client device 120, manufacturing equipment 124, sensors 126, metrology equipment 128, and data store 140 may be coupled to each other via network 130 for labeling process data. In some embodiments, network 130 may provide access to cloud-based services. Operations performed by client device 120, data store 140, etc., may be performed by virtual cloud-based devices.

In some embodiments, network 130 is a public network that provides client device 120 with access to the predictive server 112, data store 140, and other publicly available computing devices. In some embodiments, network 130 is a private network that provides client device 120 access to manufacturing equipment 124, sensors 126, metrology equipment 128, data store 140, and other privately available computing devices. Network 130 may include one or more Wide Area Networks (WANs), Local Area Networks (LANs), wired networks (e.g., Ethernet network), wireless networks (e.g., an 802.11 network or a Wi-Fi network), cellular networks (e.g., a Long Term Evolution (LTE) network), routers, hubs, switches, server computers, cloud computing networks, and/or a combination thereof.

Client device 120 may include computing devices such as Personal Computers (PCs), laptops, mobile phones, smart phones, tablet computers, netbook computers, network connected televisions (“smart TV”), network-connected media players (e.g., Blu-ray player), a set-top-box, Over-the-Top (OTT) streaming devices, operator boxes, etc.

Client device 120 may include a data labeling component 122. Data labeling component 122 may operate to label process data associated with a plurality of processed substrates so that the labeled data can be used for data analysis and/or for training a machine learning model. The data labeling component may utilize the GUI 123 to display process data, sensor data, metrology data, etc. and/or to receive user input. In some embodiments, user input may be provided via the GUI 123 to indicate a process operation of interest, a sensor of interest and/or metrology data of interest. The data labeling component 122 may label associated sensor data 142, recipe data 144, manufacturing parameters 150, and/or metrology data 160 with a common label associated with the operation of interest, sensor of interest and/or metrology data of interest, as appropriate. In some embodiments, the user input may provide an indication of the common label. For example, a user may provide a name label for the data labeling component 122 to use. In some embodiments, the data labeling component 122 links sensor data 142 and/or metrology data 160 with the operation of interest. In some embodiments, such linking is performed based at least in part on user input. For example, a user may select metrology measurements and/or sensor measurements of relevance for an operation of interest, which may cause processing logic to link the operation of interest to the selected metrology measurements and/or sensor measurements. In some embodiments, the data labeling component 122 alters the mapping of process operations (e.g., the step number of one or more process operations) to a common mapping. Upon labeling the process data, the labeled data entries may be stored in a data structure based on the label, such as in data store 140. In some embodiments, the label is used as a key to perform lookups on the updated data.

GUI 123 may include multiple user interface (UI) elements. In some embodiments, GUI 123 includes one or more fields in which a user can enter text data (e.g., indicative of a label name, etc.). In some embodiments, GUI 123 includes one or more fields for presenting process data (e.g., subsets of process data, etc.). The user may be able to select one or more data entries in the field(s) displaying process data. The selected data entries may be removed from the subset of presented data upon an indication by the user via the GUI 123. In some embodiments, the process data is presented by the GUI 123 in one or more charts for viewing by the user.

In some embodiments, a user may select an operation of interest and/or enter a partial name of an operation of interest, and all operations of a set of available recipe data/process data for instances of a recipe that was run on substrates that match or partially match the name of the selected operation of interest or partial name of the operation of interest may be presented. This may include presentation of multiple sub-operations that have been performed on one or more substrates in some embodiments. A user may deselect one or more of the presented options (e.g., may deselect one or more sub-operations) in some embodiments. In embodiments, the GUI 123 may indicate a total number of entries that are available and a number of entries for which an operation has been selected. If the total number of entries does not match the number of entries for which the operation has been selected, this may indicate to the user that the operation of interest should be selected for one or more entries (e.g., if the total number of entries is greater than the number of entries for which the operation has been selected) or that one or more operations (or sub-operations) should be deselected from one or more entries (e.g., if the total number of entries is lower than the number of entries for which the operation has been selected).

Once the data has been labeled (and optionally links have been formed between certain operations of interest and certain sensor data and/or metrology data), the labeled data may be used to present relationships (e.g., graphs, charts, etc.) between operations of interest, sensor data, and/or metrology data. Additionally, or alternatively, the labeled data may be used to train one or more machine learning models. For example, a machine learning model may be trained to perform a corrective action, to provide recipe design suggestions, etc. based on the labeled data. In some embodiments, the corrective action includes providing an alert to a user. The alert may include an alarm to stop or not perform a manufacturing process. The alert may be provided if sensor data 142, recipe data 144, manufacturing parameters 150, and/or metrology data 160 indicates an abnormality. The alert may be provided if an abnormal product, component, equipment, etc. is indicated. In some embodiments, performance of the corrective action includes causing updates to one or more manufacturing parameters 150. In some embodiments performance of a corrective action may include retraining a machine learning model associated with manufacturing equipment 124. Performance of a corrective action may include updating of other types of models associated with manufacturing equipment 124, such as adjusting a physics-based model, a process model, a virtual model, or the like. In some embodiments, performance of a corrective action may include training a new machine learning model and/or developing a new physics-based or process model associated with manufacturing equipment 124.

Manufacturing parameters 150 may include hardware parameters and/or process parameters. Hardware parameters may include information indicative of which components are installed in the manufacturing system, indications of component age, indication of software version or updates, etc. Process parameters may include temperature, pressure, gas flow rate, electrical current, voltage, lift speed, etc. In some embodiments, the corrective action includes causing preventative operative maintenance. Preventive operative maintenance may include replacing, processing, cleaning, etc., components of the manufacturing system. In some embodiments, the corrective action includes causing design optimization. Design optimization may include updating manufacturing parameters, updating manufacturing processes, and/or updating manufacturing equipment to improve performance of the manufacturing system. In some embodiments, the corrective action includes a updating a recipe. Altering a recipe may include altering the timing of manufacturing subsystems entering an idle or active mode, altering set points of various property values, or the like.

Data store 140 may be a memory (e.g., random access memory), a drive (e.g., a hard drive, a flash drive), a database system, a cloud-accessible memory system, or another type of component or device capable of storing data. Data store 140 may include multiple storage components (e.g., multiple drives or multiple databases) that may span multiple computing devices (e.g., multiple server computers). The data store 140 may store sensor data 142, recipe data 144, manufacturing parameters 150, metrology data 160, and/or label data 170.

Sensor data 142 may include historical sensor data. Sensor data may include sensor data time traces over the duration of manufacturing processes, associations of data with physical sensors, pre-processed data, such as averages and composite data, and data indicative of sensor performance over time (i.e., many manufacturing processes). Manufacturing parameters 150 and metrology data 160 may contain similar features. For example, metrology data 160 may include historical metrology data and current metrology data. Historical sensor data, historical metrology data, and historical manufacturing parameters may be historical data.

In some embodiments, a “user” may be represented as a single individual. However, other embodiments of the disclosure encompass a “user” being an entity controlled by a plurality of users and/or an automated source. For example, a set of individual users federated as a group of administrators may be considered a “user.”

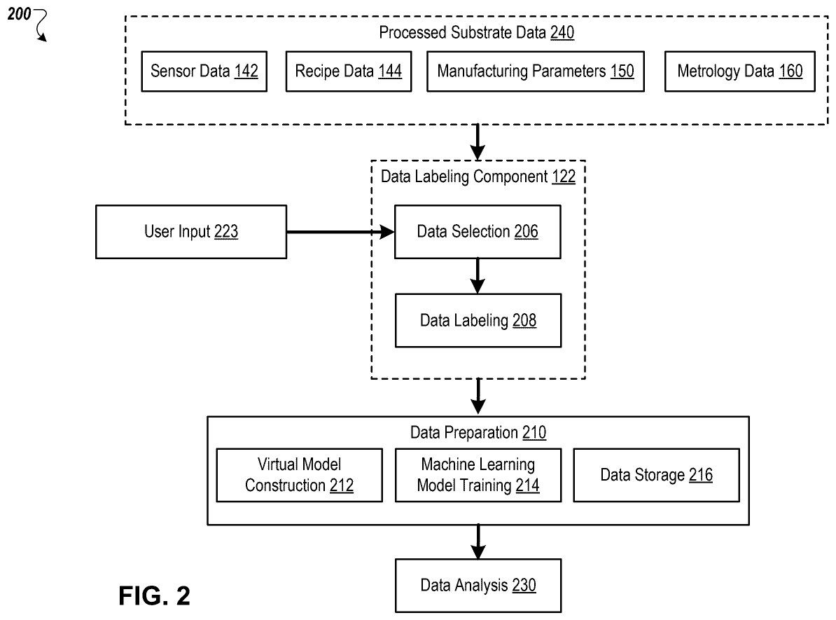

FIG. 2 depicts an exemplary data flow 200 for labeling substrate process data, according to some embodiments. In some embodiments, processed substrate data 240 is provided to data labeling component 122. Processed substrate data 240 may include sensor data 142, recipe data 144, manufacturing parameters 150, and/or metrology data 160 described herein above. In some embodiments, processed substrate data 240 is named using one or more inconsistent naming conventions. For example, and in some embodiments, one or more first data entries of the processed substrate data 240 has a first name while one or more second data entries of the processed substrate data 240 has a different second name. In some embodiments, processed substrate data 240 has inconsistent process operation mapping. For example, and in some embodiments, one or more first data entries of the processed substrate data 240 has a first operation mapping while one or more second data entries of the processed substrate data 240 has a different second operation mapping. Because the naming and/or mapping of the processed substrate data 240 is inconsistent across data entries, normalization of the data for an operation of interest may be performed and the data labeled accordingly.

The data labeling component 122 receives processed substrate data 240 and user input 223. User input 223 may include an indication and/or a selection of a process operation of interest, a sensor of interest, metrology data of interest, a name label and/or a mapping label. Data selection 206 is performed to select data 240 that is relevant and/or is to be labeled with a common label at data labeling 208. The user input 223 may be received via a UI. The UI may include a first element for presenting at least a portion of the processed substrate data 240 and a second element for receiving user input associated with the presented portion of the processed substrate data 240. In some embodiments, the user indicates a substrate process operation of interest via the second UI element. The substrate process operation of interest may be an operation the user is interested in, such as for study and/or modification of the operation, etc. In some embodiments, the UI includes a third UI element. The user may make user input, via the third UI element, selecting one or more data entries that are not relevant to the operation of interest. In some embodiments, the user selects one or more data entries that lack the operation of interest. The data entries selected by the user via the third UI element may be removed from the subset of data entries presented in the first UI element. The processed substrate data 240 presented in the first UI element is selected (e.g., at data selection 206) for labeling (e.g., at data labeling 208) based on the user input 223 as described herein above.

The selected data entries are updated by normalizing the operation of interest across the data entries. Each of the selected data entries may be modified so that each entry becomes associated with the operation of interest. The normalization may occur so that the data entries are clearly indicative of the operation of interest. Normalization of the data entries may include updating a name and/or operation mapping of the operation of interest for one or more of the data entries so that the name and/or operation mapping is common across the data entries.

The selected data entries may be labeled, at data labeling 208, with a common label. The common label may be an indicator of a common name or an indicator of a common process mapping. The common label may be indicative of the data normalization. For example, and in some embodiments, the common label is a name assigned to the normalized data entries. In another example, and in some embodiments, the common label is a process mapping assigned to the normalized data entries.

In some embodiments, the processed substrate data 240 is selected based on a measurement of interest. A measurement of interest may be determined from a plurality of data entries of the processed substrate data 240. The processed substrate data 240 may include data entries having a first measurement name and other data entries having a different second measurement name. The data entries may be updated by normalizing the measurement of interest across the data entries. The data entries corresponding to the normalized measurement of interest may be appropriately labeled with a common label associated with the normalized measurement of interest. For example, the data entries may be labeled with a name of the measurement of interest.

In some embodiments, the processed substrate data 240 is selected based on a sensor of interest. A sensor of interest may be determined from a plurality of data entries of the processed substrate data 240. The processed substrate data 240 may include data entries having a first sensor name and other data entries having a different second sensor name. The data entries may be updated by normalizing the sensor of interest across the data entries. The data entries corresponding to the normalized sensor of interest may be appropriately labeled with a common label associated with the normalized sensor of interest. For example, the data entries may be labeled with a name of the sensor of interest.

In some embodiments, data entries comprising the metrology data 160 are normalized according to the operation of interest. Each of the metrology data entries may be modified so that each entry becomes associated with the operation of interest. The normalization may occur so that the data entries are clearly indicative of the operation of interest. Normalization of the metrology data 160 may include updating a name and/or mapping, etc. of the metrology data for one or more data entries so that the name and/or mapping, etc. is common across the metrology data entries.

The updated data entries (e.g., the labeled data entries labeled with the common label, etc.) are prepared for one or more data analysis operations based on the common label at data preparation 210. Data preparation 210 may include virtual model construction 212, machine learning model training 214, and/or data storage 216. Virtual model construction 212 may include the generation (e.g., construction, etc.) of a virtual model using the labeled data entries associated with the operation of interest, sensor of interest, measurement of interest and/or metrology data of interest. The virtual model may be a virtual representation of a substrate process operation, a substrate process sub-operation, or a complete substrate process. For example, and in some embodiments, the virtual model may be a virtual representation of the operation of interest. In some embodiments, the constructed virtual model is a representation of multiple combined process operations, combined into a single virtual process operation. The virtual model may be configured to provide predicted output data (e.g., such as predicted metrology data, etc.) based on input data (e.g., such as input sensor data 142, input recipe data 144, and/or input manufacturing parameters 150, etc.).

In some embodiments, virtual model construction 212 includes generating a virtual sensor measurement for the virtual operation. The virtual sensor measurement may be an estimated or inferred sensor measurement of a physical quantity or value (e.g., such as a process chamber condition, etc.) that may be determined without directly measuring the physical quantity or value. The virtual sensor measurement may be based on a mathematical model, algorithm, or other data applied to one or more other sensor measurements. In some embodiments, the virtual sensor measurement is based on applying a weighted average of one or more sensor measurements associated with one or more existing operations. For example, and in some embodiments, sensor data 142 from one or more process operations can be used to generate a virtual sensor measurement that is to encapsulate the execution of the one or more process operations. The virtual sensor measurement can take a weighted average of the corresponding sensor data 142 based on process parameters such as duration, etc.

In some embodiments, sensor data 142 for two or more process operations can be used to generate a virtual sensor measurement for a virtual operation that is a combination of the two or more operations. For example, for some data entries an operation of interest may not be included, but the data entries may include a combination of other operations (e.g., sub-operations) that together are an equivalent to the operation of interest. However, the sensor data for the other operations may provide different values than the values of the sensor measurements for the operation of interest in those data entries that include the operation of interest. In such an instance, processing logic may determine a virtual measurement based on computing an average (e.g., a weighted average) of sensor measurements of the two or more other operations that is comparable to the sensor measurements of the operation of interest. This may enable the sensor measurements to be compared between the different data entries, and to be labeled with a common label.

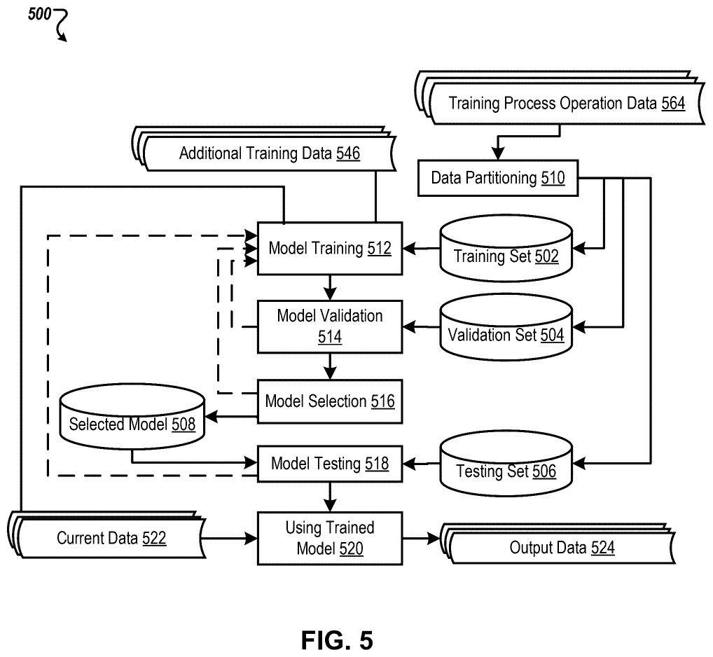

Machine learning model training 214 may include the training of a machine learning model to produce a trained machine learning model, such as set forth in FIG. 5. Training the machine learning model may include providing labeled data entries associated with the operation of interest, sensor(s) of interest, sensor measurement(s) of interest and/or metrology data of interest as training input data and/or as training output data. The trained machine learning model may be representative of one or more process operations, such as the operation of interest. The trained machine learning model (e.g., trained with labeled data entries, etc.) may be configured to output predicted data (e.g., such as predicted metrology data, etc.) based on input data (e.g., such as input sensor data/measurements 142, input recipe data 144, and/or input manufacturing parameters 150, etc.).

The updated data entries (e.g., the labeled data entries, labeled with the common label, etc.) may be stored. Data storage 216 may include preparing the updated data entries for storage, such as in a data structure, etc. In some embodiments, the updated data entries are saved in a data structure for later access.

Once the data has been labeled and prepared, data analysis 230 can commence. Data analysis may include one or more data analysis operations, such as statistical analysis, etc. In some embodiments, data analysis 230 includes utilization of a virtual model and/or utilization of a trained machine learning model. Use of a virtual model and/or trained machine learning model may provide predicted data that can be used for updating one or more substrate process operations, such as the operation of interest. In some embodiments, statistical analysis is performed so that a user (e.g., such as an engineer or technician, etc.) can make updates to the operation of interest based on the statistical analysis.

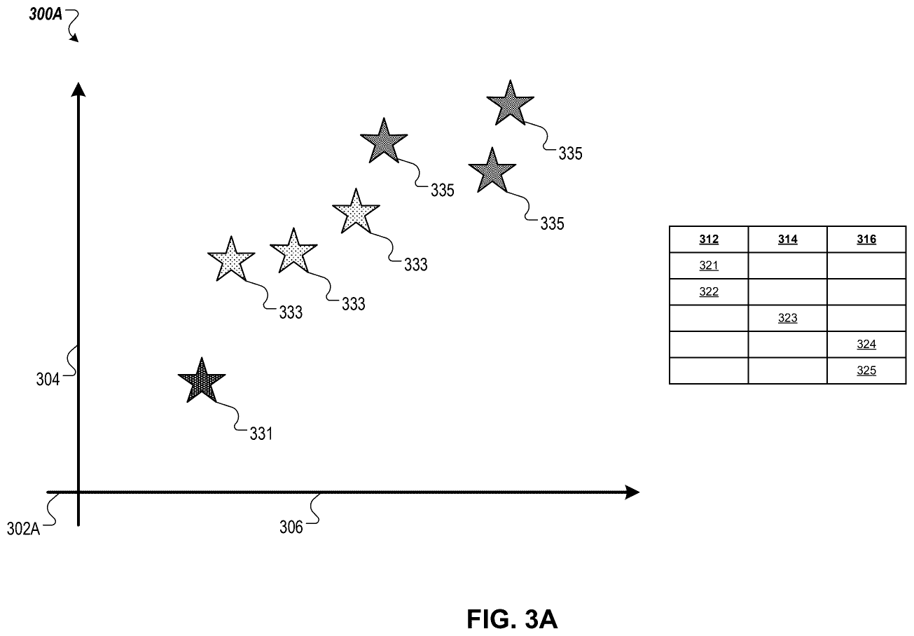

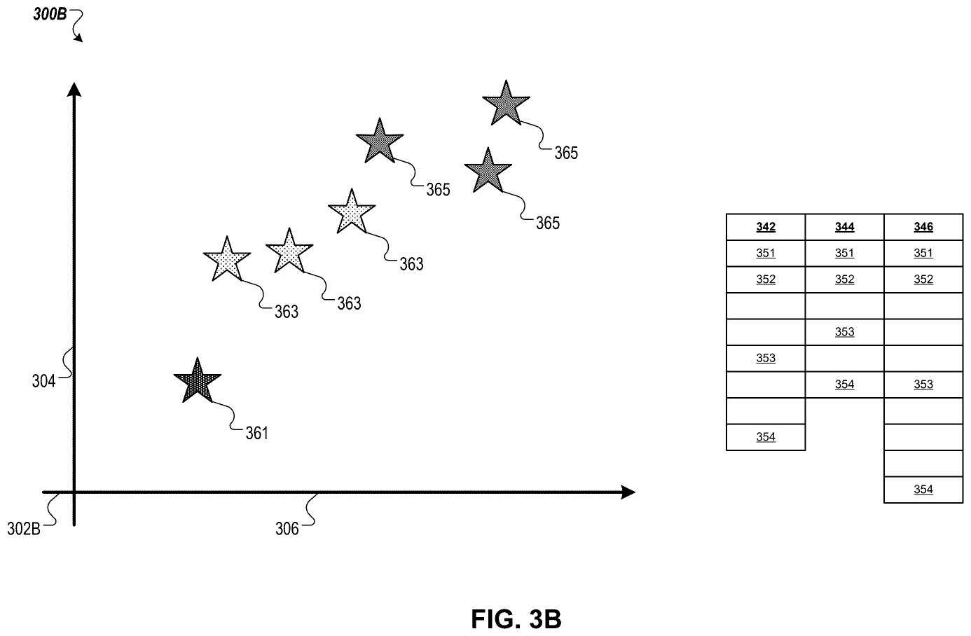

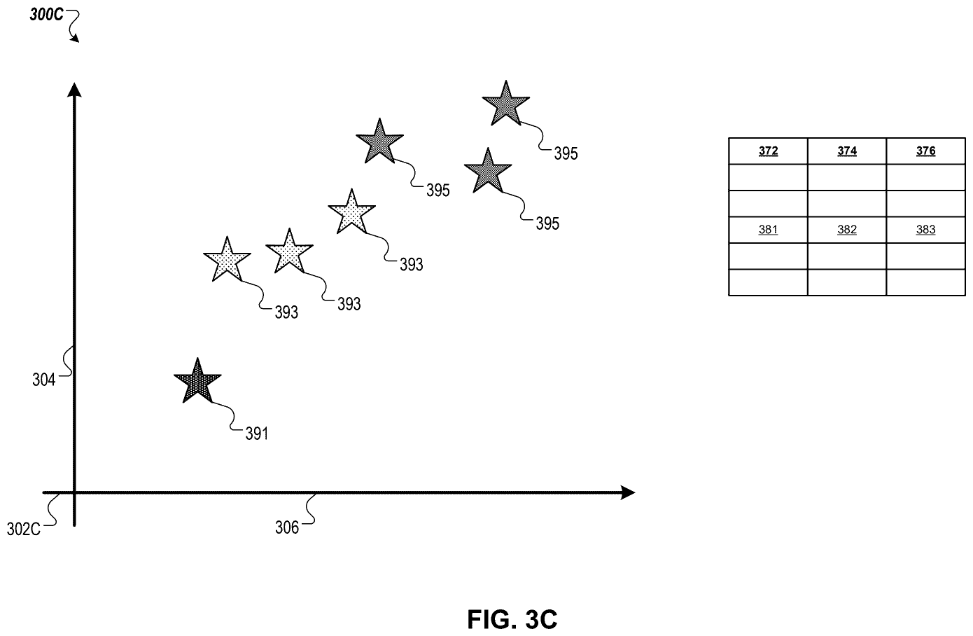

FIGS. 3A-C depict exemplary data mapping for substrate process data, according to some embodiments. Referring to FIG. 3A, an example mapping 300A is depicted. Process data is shown plotted on chart 302A. The process data may be associated with a substrate process operation, such as a process operation of interest. The horizontal axis 306 may be associated with a process parameter (e.g., a process knob setting such as temperature setting, gas flow setting, duration setting, etc.) and the vertical axis 304 may be associated with a metrology measurement. Data points (illustrated as stars plotted on chart 302A) may correspond to particular metrology measurements associated with a value of the process parameter (e.g., represented on axis 306). In some embodiments, inconsistent naming conventions of the datasets can allow the data points not to be linked to one another. For example, and in some embodiments, data 331 may be saved (e.g., by a user) with a first name 312, data 333 may be saved with a different second name 314, and data 335 may be saved with a different third name 316. However, data 331, 333, and 335 may all correspond to the same process operation. In a data structure, for example, data entries 321 and 322 may be associated with first name 312, data entry 323 may be associated with second name 314, and data entries 324 and 325 may be associated with third name 316. Again, however, each of the data entries 321-325 may be correspond to the same process operation. Data entries 321-325 may correspond to data 331, 333, and/or 335. Because the data entries are not commonly named, meaningful data analysis cannot be easily performed. According to embodiments described herein, each of the data entries 321-325 may be labeled with a common label (e.g., such as a common name label, etc.) so that the data entries can be easily identified for data analysis operations.

Referring to FIG. 3B, an example mapping 300B is depicted. Process data is shown plotted on chart 302B. The process data may be associated with a substrate process, such as a process recipe, etc. Process data associated with recipe 342, recipe 344, and/or recipe 346 may be plotted on chart 302B. For example, data 361 may be associated with recipe 342, data 363 may be associated with recipe 344, and data 365 may be associated with recipe 346. In some embodiments, each of the recipes 342, 344, and/or 346 may include a first recipe operation 351, a second recipe operation 352, a recipe operation of interest 353, and a final recipe operation 354. However, each of the recipes 342, 344, and/or 346 may include a different number of recipe operations. For example, recipe 342 may include eight operations, recipe 344 may include six operations, and recipe 346 may include ten operations. Accordingly, the operation of interest 353 of each of the recipes may have different mapping in each of the recipes and may not be mapped to the same recipe operation. For example, the operation of interest 353 is the fifth operation in recipe 342, the fourth operation in recipe 344, and the sixth operation in recipe 346. The operation of interest 353 may have different mapping in each of the recipes because recipe operations may be broken into multiple sub-operations. For example, an etch operation in recipe 344 may be separated into two etch operations in recipe 342 or four etch operations in recipe 346, etc. In some embodiments, the process data for each of the recipes is updated by normalizing the operation of interest 353 across the data. For example, the process data is normalized based on the operation of interest 353 so that data corresponding to the operation of interest 353 of each of the recipes is correctly mapped. Once the data is normalized, the mapping of each of the process recipes may be updated and the data labeled with a common label (e.g., a common mapping label, etc.). The labeled data (e.g., with common and/or normalized mapping, etc.) can be used for data analysis operations as described herein.

Referring to FIG. 3C, an example mapping 300C is depicted. Process data is shown plotted on chart 302C. In some embodiments, data entries are associated with different process chambers, such as chamber 372, chamber 374, and/or chamber 376. Each of the chambers may include the same type(s) of sensors and may perform the same process operations. In some embodiments, data 391 is associated with chamber 372, data 393 is associated with chamber 374, and data 395 is associated with chamber 376. Each of the chambers may include multiple sensors, including a sensor of interest. However, in the collected data for each of the chambers, different names and/or naming conventions may be used for the sensor of interest. For example, the sensor of interest may have a first name 381 in the data associated with chamber 372, the sensor of interest may have a different second name 382 in the data associated with chamber 374, and the sensor of interest may have a different third name 383 in the data associated with chamber 376. In some embodiments, the process data entries are updated by normalizing the sensor of interest across the data entries and labeling the data entries with a common label associated with the normalized sensor of interest. For example, the data entries associated with the sensor of interest may be labeled with a common name so that the data entries are identifiable as corresponding to the sensor of interest.

In some embodiments, data associated with a measurement of interest is collected during substrate processing. Similar to the sensor of interest described above, the measurement of interest may have different naming across different process chambers and/or processes. The process data entries may be updated by normalizing the measurement of interest across the data entries and labeling the data entries with a common label associated with the normalized measurement of interest.

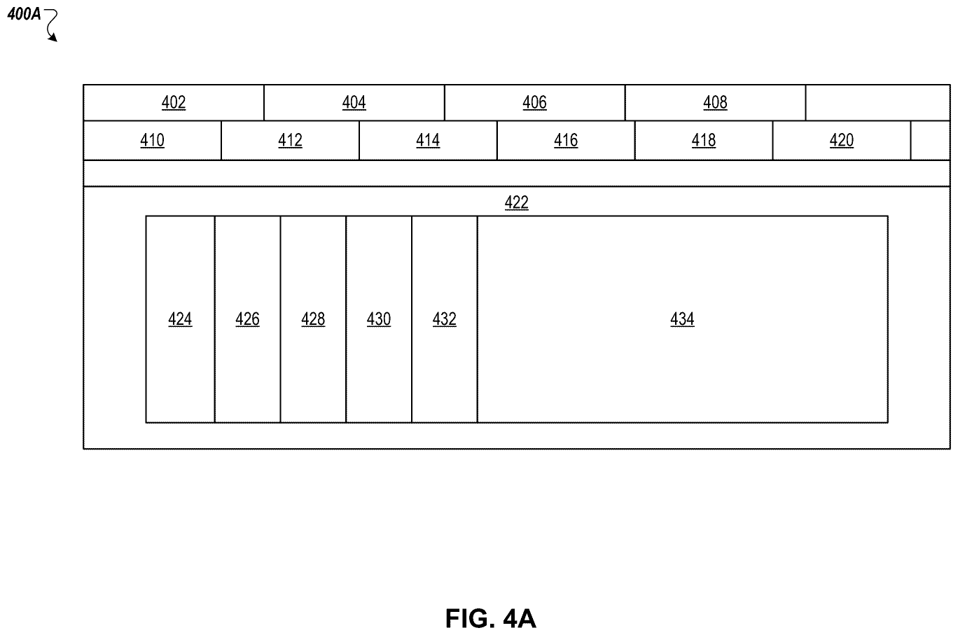

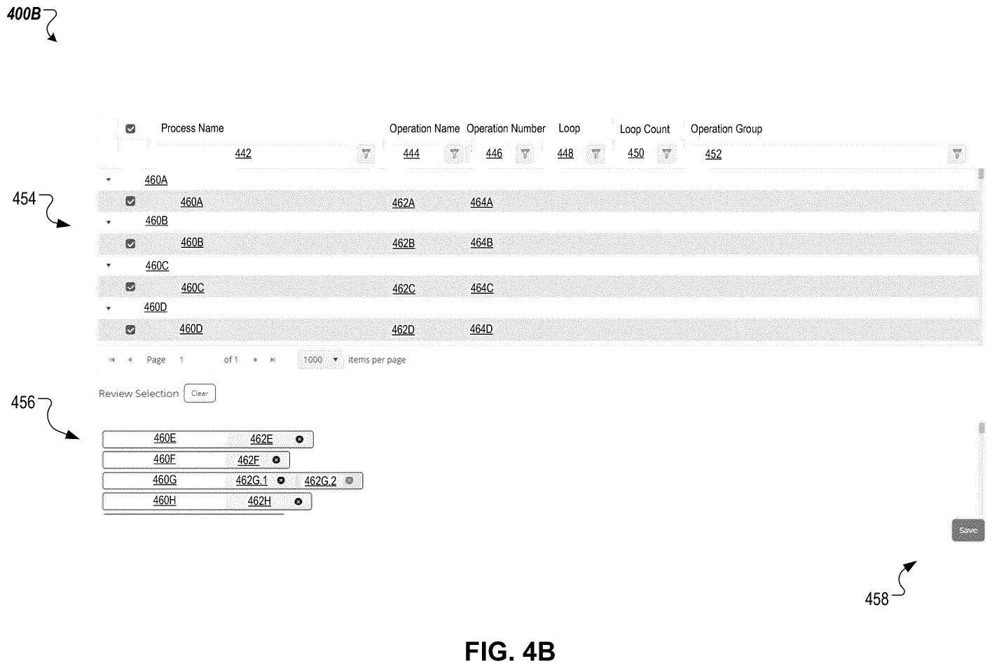

FIGS. 4A-B depict example user interface (UI) elements, according to some embodiments. Referring to FIG. 4A, a first UI 400A is shown. The UI 400A includes multiple UI elements. In some embodiments, UI elements 402-408 are operable to change the view for presenting datasets (e.g., of process data) in display element 422. Element 402-408 may be selected to change the view shown in display element 422. For example, the view shown in display element 422 can be one of a chart view, a recipe operation view, a metrology view, and/or a spreadsheet view. Each of the different views may provide a different visualization of the data entries. In some embodiments, UI elements 410-420 are operable to open one or more widgets and/or perform one or more functions for aiding in labeling of process data. Element 410 may be selected to show an individual view of a process recipe operation. For example, when element 410 is selected, a view for an individual process recipe operation is shown. Element 412 may be selected to show all process recipe operations. For example, when element 412 is selected, a view for all process recipe operations is shown. Element 414 may be selected to open a widget for identifying and/or mapping a process operation of interest. In some embodiments, when element 414 is selected, a second UI 400B may be opened. Element 416 may be selected to freeze a top row displayed in display element 422. For example, when element 416 is selected, the top row displayed in display element 422 becomes frozen so that the data in the top row does not move. Element 418 may be selected to sort the data displayed in display element 422, such as by a drop-down menu, etc. For example, when element 418 is selected, a drop-down menu may appear showing multiple filters for sorting the data displayed in the display element 422. Element 420 may be selected to refresh the data displayed in display element 422. For example, when element 420 is selected, the data displayed in display element 422 is refreshed. In some embodiments, data shown in display element 422 is shown in the form of a spreadsheet. In some embodiments, the data is displayed in rows and columns. For each of the data entries, a column 424 may display an operation name, a column 426 may show an operation number, a column 428 may show a pressure, a column 430 may show a time, a column 432 may show a gas, and one or more columns 434 may show a source, etc. corresponding to the data entries.

Referring to FIG. 4B, a second UI 400B is shown. The second UI 400B includes multiple UI elements. UI elements 454 and 456 are display elements. In some embodiments, display element 454 presents data entries for recipe operations. The display element 454 may include a chart to display data entries. In some embodiments, display element 454 shows data entries organized in rows and/or columns. For example, and in some embodiments, for multiple data entries each corresponding to a process operation, a process name 460A-460D, an operation name 462A-D, and/or an operation number 464A-D may be displayed in the display element 454.

UI elements 442-452 are features for organizing data shown in UI element 454. For example, elements 442-452 are operable to filter the data shown in UI element 454. Each of the elements 442-452 may include one or more fields configured to receive user input. In some embodiments, a user can enter a process name (e.g., a recipe name, etc.) in a field provided by element 442. The data presented in the UI element 454 is searched for the entered process name. Data corresponding to the searched process name displayed in UI element 454 may then be presented in UI element 456. In some embodiments, a user can enter a process operation name in a field provided by UI element 444. The data presented in the UI element 454 is searched for the entered process operation name. Data corresponding to the searched process operation name displayed in UI element 454 may then be presented in UI element 456. In some embodiments, a user can enter a process operation number (e.g., an identifier, etc.) in a field provided by UI element 446. The data presented in the UI element 454 is searched for the entered process operation number name. Data corresponding to the searched process operation number displayed in UI element 454 may then be presented in UI element 456. In some embodiments, a user can enter a query associated with a process loop in a field provided by UI element 448. The data presented in the UI element 454 is searched for the entered query. Data corresponding to the searched query displayed in UI element 454 may then be presented in UI element 456. In some embodiments, a user can enter a loop count in a field provided by UI element 450. A loop count may be an attribute of a recipe operation. In some embodiments, a loop count is the number of times an operation is run in a loop (e.g., the operation is repeated) during execution of the recipe. The data presented in the UI element 454 is searched for the entered loop number. Data corresponding to the searched loop count displayed in UI element 454 may then be presented in UI element 456. For example, recipe operations displayed in UI element 454 having the entered loop count from UI element 450 are presented in UI element 456. In some embodiments, a user can enter an identifier associated with an operation group in a field provided by UI element 452. The data presented in the UI element 454 is searched for the entered operation group. Data corresponding to the searched identifier displayed in UI element 454 may then be presented in UI element 456.

In some embodiments, the UI element 456 is an element for reviewing data. Display element 456 may show data entries searched, filtered, and/or selected from display element 454. For example, data entries including a process name 460E-H and a corresponding operation name 462E-H may be displayed in the display element 456, each of the displayed data entries having been selected and/or filtered from the data entries displayed in display element 454. Data entries corresponding to entered queries entered in UI elements 442-452 may be presented in the UI element 456. In some embodiments, the user may select data presented in element 456 to remove the data from the dataset. In some embodiments, the user selects data entries that lack the operation of interest. The user may select one or more displayed data entries in the UI element 456. The selected data entries are removed from the dataset. For example, two operations having names 462G.1 and 462G.2 may have been found in the data displayed in element 454 and thus displayed in element 456. One of the two operations may be irrelevant and/or may not be associated with the entered query (e.g., lacks the operation of interest, etc.). Therefore, one of the operations, such as the operation having name 462G.2, may be removed from the displayed dataset. In some embodiments, the UI element 456 shows statistics associated with the dataset, such as a total number of processes represented by the displayed data and/or a total number of process operations represented by the displayed data.

The data entries presented in the UI element 456 may be labeled with a common label. In some embodiments, the user inputs a label (e.g., such as a label name, etc.) into the UI element 458. The label is then associated with each of the data entries in the UI element 456. Once labeled, the data entries can be prepared for data analysis, etc. In some embodiments, a data table (e.g., a spreadsheet, etc.) is generated to display at least a portion of the data entries labeled with the common label.

FIG. 5 is a block diagram illustrating a method for training and using a machine learning model, according to some embodiments. The trained machine learning model may be used to perform data analysis on data labeled according to embodiments described herein. In some embodiments, the trained machine learning model can be used to predict process data and/or to predict updates to process operations based on input data.

At block 510, method 500 performs data partitioning of data to be used in training, validating, and/or testing a machine learning model. In some embodiments, training process operation data 564 includes historical data, such as historical process operation data, historical process parameter data, historical sensor data, etc. The training process operation data 564 may include data from data entries labeled with a common label as described herein. In some embodiments, process operation data may be provided by a data labeling component, e.g., data labeling component 122 of FIG. 1. Training process operation data 564 may undergo data partitioning at block 510 to generate training set 502, validation set 504, and testing set 506. For example, the training set may be 60% of the training data, the validation set may be 20% of the training data, and the testing set may be 20% of the training data.

The generation of training set 502, validation set 504, and testing set 506 may be tailored for a particular application. For example, the training set may be 60% of the training data, the validation set may be 20% of the training data, and the testing set may be 20% of the training data. Method 500 may generate a plurality of sets of features for each of the training set, the validation set, and the testing set. Different models may be trained on different sets of data.

At block 512, method 500 performs model training using training set 502. Training of a machine learning model and/or of a physics-based model (e.g., a digital twin) may be achieved in a supervised learning manner, which involves providing a training dataset including labeled inputs through the model, observing its outputs, defining an error (by measuring the difference between the outputs and the label values), and using techniques such as deep gradient descent and backpropagation to tune the weights of the model such that the error is minimized. In many applications, repeating this process across the many labeled inputs in the training dataset yields a model that can produce correct output when presented with inputs that are different than the ones present in the training dataset. In some embodiments, training of a machine learning model may be achieved in an unsupervised manner, e.g., labels or classifications may not be supplied during training. An unsupervised model may be configured to perform anomaly detection, result clustering, etc.

For each training data item in the training dataset, the training data item may be input into the model (e.g., into the machine learning model). The model may then process the input training data item (e.g., an image of a substrate etc.) to generate an output. The output may include, for example, information defects of the substrate (e.g., a characterization of the substrate defects, one or more matches to historical defects, etc.). The output may be compared to a label of the training data item (e.g., information generated by another reliable method).

Processing logic may then compare the generated output (e.g., substrate defect information) to the label (e.g., labeled substrate information) that was included in the training data item. Processing logic determines an error (i.e., a classification error) based on the differences between the output and the label(s). Processing logic adjusts one or more weights and/or values of the model based on the error.

In the case of training a neural network, an error term or delta may be determined for each node in the artificial neural network. Based on this error, the artificial neural network adjusts one or more of its parameters for one or more of its nodes (the weights for one or more inputs of a node). Parameters may be updated in a back propagation manner, such that nodes at a highest layer are updated first, followed by nodes at a next layer, and so on. An artificial neural network contains multiple layers of “neurons”, where each layer receives as input values from neurons at a previous layer. The parameters for each neuron include weights associated with the values that are received from each of the neurons at a previous layer. Accordingly, adjusting the parameters may include adjusting the weights assigned to each of the inputs for one or more neurons at one or more layers in the artificial neural network.

At block 514, method 500 performs model validation (e.g., via a validation engine, etc.) using the validation set 504. The method 500 may validate each of the trained models using a corresponding set of features of the validation set 504. Responsive to determining that one or more of the trained models has an accuracy that meets a threshold accuracy, flow continues to block 516.

At block 516, method 500 may perform model selection (e.g., via a selection engine, etc.) to determine which of the one or more trained models that meet the threshold accuracy has the highest accuracy (e.g., the selected model 508, based on the validating of block 514). Responsive to determining that two or more of the trained models that meet the threshold accuracy have the same accuracy, flow may return to block 512 where the method 500 performs model training using further refined training sets corresponding to further refined sets of features for determining a trained model that has the highest accuracy.

At block 518, method 500 performs model testing using testing set 506 to test selected model 508. Method 500 may test the first trained model to determine the first trained model meets a threshold accuracy. Determining whether the first trained model meets a threshold accuracy may be based on the first set of features of testing set 506. Responsive to accuracy of the selected model 508 not meeting the threshold accuracy, flow continues to block 512 where method 500 performs model training (e.g., retraining) using different training sets corresponding to different sets of features. Accuracy of selected model 508 may not meet threshold accuracy if selected model 508 is overly fit to the training set 502 and/or validation set 504. Responsive to determining that selected model 508 has an accuracy that meets a threshold accuracy based on testing set 506, flow continues to block 520. In at least block 512, the model may learn patterns in the training data to make classifications. In block 518, the method 500 may apply the model on the remaining data (e.g., testing set 506) to test the classifications.

At block 520, method 500 uses the trained model (e.g., selected model 508) to receive current data 522 and determines (e.g., extracts), from the output of the trained model, output data 524. Current data 522 may be data related to one or more processed substrates, in some embodiments. Current data 522 may be metrology data of at least a portion of a substrate of interest in some embodiments. Current data 522 may be data associated with a process operation of interest, such as sensor data, measurement data, manufacturing parameter data, etc. A corrective action associated with the manufacturing equipment 124 of FIG. 1 may be performed in view of output data 524. The corrective action may include the updating of a process operation, such as the process operation of interest, etc.

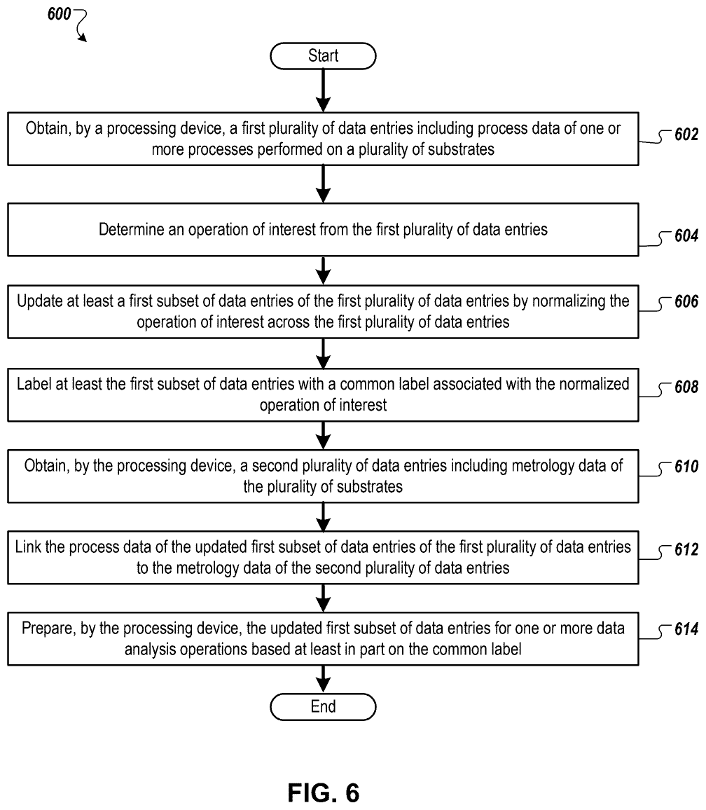

FIG. 6 is a flow diagram of a method 600 for labeling substrate process data, according to some embodiments. Method 600 may be performed by processing logic that may include hardware (e.g., circuitry, dedicated logic, programmable logic, microcode, processing device, etc.), software (such as instructions run on a processing device, a general purpose computer system, or a dedicated machine), firmware, microcode, or a combination thereof. In some embodiment, method 600 may be performed, in part, by data labeling component 122. In some embodiments, a non-transitory machine-readable storage medium storing instructions that when executed by a processing device (e.g., of data labeling component 122, etc.) cause the processing device to perform method 600.

For simplicity of explanation, method 600 is depicted and described as a series of operations. However, operations in accordance with this disclosure can occur in various orders and/or concurrently and with other operations not presented and described herein. Furthermore, not all illustrated operations may be performed to implement method 600 in accordance with the disclosed subject matter. In addition, those skilled in the art will understand and appreciate that method 600 could alternatively be represented as a series of interrelated states via a state diagram or events.

At block 602, processing logic obtains a first plurality of data entries including process data of one or more processes performed on a plurality of substrates. Each data entry includes process data for a plurality of operations of the processes. A first set of data entries has a different operation mapping or different operation names than a second set of data entries. For example, the first set of data entries may include data from more or fewer process operations than the second set of data, and thus may have different operation mapping. In another example, the first set of data entries may be associated with process operations having different names than the second set of data. One or more of the process operations may nevertheless correspond to one another (e.g., are the same, etc.).

At block 604, processing logic determines an operation of interest from the first plurality of data entries. For the first set of data entries, the operation of interest has a first operation mapping in the one or more processes or a first operation name. For the second set of data entries, the operation of interest has a different second operation mapping in the one or more processes or a different second operation name.

At block 606, processing logic updates at least a first subset of data entries of the first plurality of data entries by normalizing the operation of interest across the first plurality of data entries. In some embodiments, the processing logic identifies the operation of interest and associates data entries corresponding to the operation of interest across the plurality of data entries. In some embodiments, a user provides input indicative of the operation of interest, such as via a GUI. In some embodiments, normalization of the data includes mapping the corresponding data entries to one another and/or assigning an operation name to the corresponding data entries.

At block 608, processing logic labels at least the first subset of data entries with a common label associated with the normalized operation of interest. The common label may be a name label, a mapping label, or an indicator of such. In some embodiments, the user provides text input indicative of the common label. For example, the user can enter, via a GUI, a text name for the first subset of data entries.

At block 610, processing logic obtains a second plurality of data entries including metrology data of the plurality of substrates. The second plurality of data entries may include measurement data for the plurality of substrates as described herein. The metrology data may have been collected subsequent to the processing of the plurality of substrates.

At block 612, processing logic links the process data of the updated first subset of data entries of the first plurality of data entries to the metrology data of the second plurality of data entries. In some embodiments, the data is linked by marking the data entries with an identifier that correlates corresponding data entries to one another.

At block 614, processing logic prepare the updated first subset of data entries for one or more data analysis operations based at least in part on the common label. In some embodiments, processing logic generates a virtual model and/or trains a machine learning model using the labeled data. In some embodiments, the processing logic stores the labeled data in a data structure. Using the labeled data, data analysis can be performed to predict metrology data and/or to predict updates associated with the operation of interest.

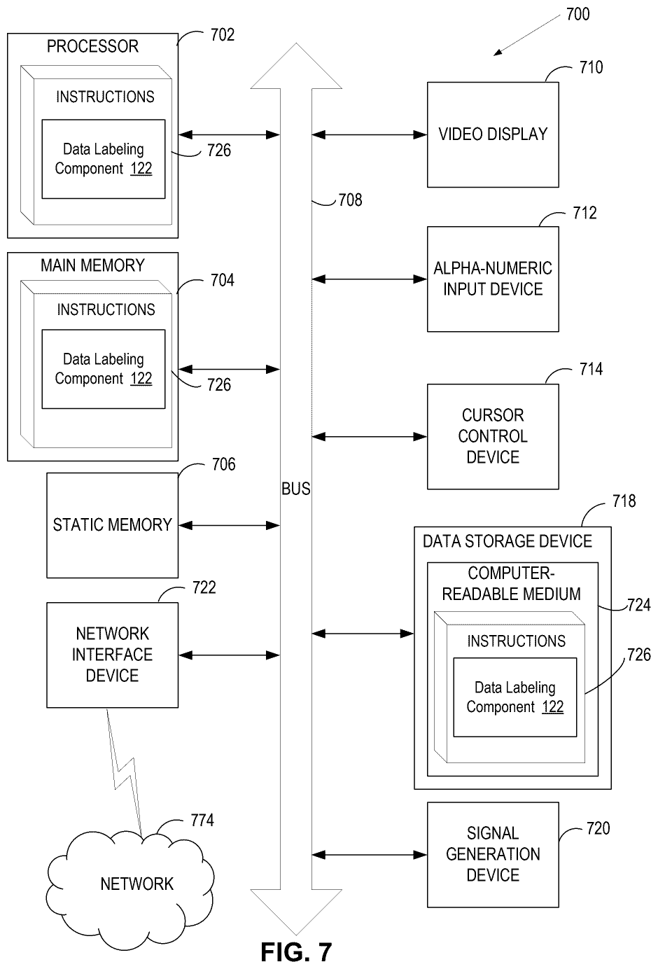

FIG. 7 is a block diagram illustrating a computer system 700, according to some embodiments. In some embodiments, computer system 700 may be connected (e.g., via a network, such as a Local Area Network (LAN), an intranet, an extranet, or the Internet) to other computer systems. Computer system 700 may operate in the capacity of a server or a client computer in a client-server environment, or as a peer computer in a peer-to-peer or distributed network environment. Computer system 700 may be provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 700 may include a processing device 702, a volatile memory 704 (e.g., Random Access Memory (RAM)), a non-volatile memory 706 (e.g., Read-Only Memory (ROM) or Electrically-Erasable Programmable ROM (EEPROM)), and a data storage device 718, which may communicate with each other via a bus 708.

Processing device 702 may be provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

Computer system 700 may further include a network interface device 722 (e.g., coupled to network 774). Computer system 700 also may include a video display unit 710 (e.g., an LCD), an alphanumeric input device 712 (e.g., a keyboard), a cursor control device 714 (e.g., a mouse), and a signal generation device 720.

In some embodiments, data storage device 718 may include a non-transitory computer-readable storage medium 724 (e.g., non-transitory machine-readable medium) on which may store instructions 726 encoding any one or more of the methods or functions described herein, including instructions encoding components of FIG. 1 (e.g., data labeling component 122, etc.) and for implementing methods described herein. Instruction 726 may encode functions performed by additional components, including GUI 123, etc.

Instructions 726 may also reside, completely or partially, within volatile memory 704 and/or within processing device 702 during execution thereof by computer system 700, hence, volatile memory 704 and processing device 702 may also constitute machine-readable storage media.

While computer-readable storage medium 724 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The methods, components, and features described herein may be implemented by discrete hardware components or may be integrated in the functionality of other hardware components such as ASICS, FPGAs, DSPs or similar devices. In addition, the methods, components, and features may be implemented by firmware modules or functional circuitry within hardware devices. Further, the methods, components, and features may be implemented in any combination of hardware devices and computer program components, or in computer programs.

Unless specifically stated otherwise, terms such as “receiving,” “performing,” “providing,” “obtaining,” “causing,” “determining,” “using,” “training,” “generating,” “correcting,” “updating,” “scheduling,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and may not have an ordinal meaning according to their numerical designation.

Examples described herein also relate to an apparatus for performing the methods described herein. This apparatus may be specially constructed for performing the methods described herein, or it may include a general purpose computer system selectively programmed by a computer program stored in the computer system. Such a computer program may be stored in a computer-readable tangible storage medium.

The methods and illustrative examples described herein are not inherently related to any particular computer or other apparatus. Various general purpose systems may be used in accordance with the teachings described herein, or it may prove convenient to construct more specialized apparatus to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and embodiments, it will be recognized that the present disclosure is not limited to the examples and embodiments described. The scope of the disclosure should be determined with reference to the following claims, along with the full scope of equivalents to which the claims are entitled.

What is claimed is:

1. A method comprising:
obtaining, by a processing device, a first plurality of data entries comprising process data of one or more processes performed on a plurality of substrates, wherein each data entry of the first plurality of data entries comprises process data for a plurality of operations of the one or more processes, wherein one or more first data entries of the first plurality of data entries has at least one of a different operation mapping or different operation names than one or more second data entries of the first plurality of data entries;
determining an operation of interest from the first plurality of data entries, wherein for the one or more first data entries the operation of interest has at least a first operation mapping in the one or more processes or a first operation name, and wherein for the one or more second data entries the operation of interest has at least one of a second operation mapping in the one or more processes or a second operation name;
updating at least a first subset of data entries of the first plurality of data entries by normalizing the operation of interest across the first plurality of data entries;
labeling at least the first subset of data entries with a common label associated with the normalized operation of interest;
obtaining, by the processing device, a second plurality of data entries comprising metrology data of the plurality of substrates;
linking the process data of the updated first subset of data entries of the first plurality of data entries to the metrology data of the second plurality of data entries; and
preparing, by the processing device, the updated first subset of data entries for one or more data analysis operations based at least in part on the common label.

2. The method of claim 1, wherein determining the operation of interest comprises:
providing, by the processing device, a user interface (UI), the UI comprising a first UI element for presenting at least a portion of the data entries and a second UI element for receiving user input associated with at least the portion of the data entries; and
receiving, via the second UI element, first user input selecting the operation of interest in at least one data entry of the first plurality of data entries.

3. The method of claim 2, further comprising:
presenting, via the first UI element, the first subset of data entries;
receiving, via a third UI element of the UI, second user input selecting one or more data entries of the first subset of data entries; and
removing the selected one or more data entries from the first subset of data entries.

4. The method of claim 2, wherein the first UI element comprises a chart to display the at least a portion of the data entries, and wherein the second UI element comprises one or more fields configured to receive the first user input.

5. The method of claim 1, further comprising:
training a machine learning model using the updated first subset of data entries and linked second plurality of data entries to form a trained machine learning model, wherein the one or more data analysis operations are performed using the trained machine learning model.

6. The method of claim 1, further comprising:
determining a measurement of interest from the second plurality of data entries, wherein for one or more third data entries the measurement of interest has a first measurement name, and wherein for one or more fourth data entries the measurement of interest has a second measurement name;
updating at least a second subset of data entries of the second plurality of data entries by normalizing the measurement of interest across the second plurality of data entries; and
labeling at least the second subset of data entries with a second common label associated with the normalized measurement of interest;
wherein the normalized operation of interest from the first subset of data entries is linked to the normalized measurement of interest from the second subset of data entries.

7. The method of claim 1, further comprising:
determining a sensor of interest from the first plurality of data entries, wherein for one or more third data entries the sensor of interest has a first sensor name, and wherein for one or more fourth data entries the sensor of interest has a second sensor name;
updating at least the first subset of data entries by normalizing the sensor of interest across the first plurality of data entries; and
labeling at least the first subset of data entries with a second common label associated with the normalized sensor of interest.

8. The method of claim 1, wherein preparing the first subset of the data entries for one or more data analysis operations comprises storing the first subset of the data entries in a data structure based on the label.

9. The method of claim 1, further comprising:
generating one or more charts comprising information for the operation of interest on a first axis and information for the metrology data on a second axis from the updated first subset of data entries.

10. The method of claim 1, further comprising:
determining one or more third data entries of the first plurality of data entries that lack the operation of interest; and
generating a virtual operation for the one or more third data entries based on a combination of two or more existing operations in the one or more third data entries, wherein the virtual operation corresponds to the operation of interest.

11. The method of claim 10, further comprising:
generating a virtual sensor measurement for the virtual operation based on applying a weighted average of one or more sensor measurements associated with the two or more existing operations.

12. A system, comprising:
a memory; and
a processing device operatively coupled to the memory, wherein the processing device is configured to:
obtain a first plurality of data entries comprising process data of one or more processes performed on a plurality of substrates, wherein each data entry of the first plurality of data entries comprises process data for a plurality of operations of the one or more processes, wherein one or more first data entries of the first plurality of data entries has at least one of a different operation mapping or different operation names than one or more second data entries of the first plurality of data entries;
determine an operation of interest from the first plurality of data entries, wherein for the one or more first data entries the operation of interest has at least a first operation mapping in the one or more processes or a first operation name, and wherein for the one or more second data entries the operation of interest has at least one of a second operation mapping in the one or more processes or a second operation name;
update at least a first subset of data entries of the first plurality of data entries by normalizing the operation of interest across the first plurality of data entries;
label at least the first subset of data entries with a common label associated with the normalized operation of interest;
obtain a second plurality of data entries comprising metrology data of the plurality of substrates;
link the process data of the updated first subset of data entries of the first plurality of data entries to the metrology data of the second plurality of data entries; and
prepare the updated first subset of data entries for one or more data analysis operations based at least in part on the common label.

13. The system of claim 12, wherein to determine the operation of interest, the processing device is to:
provide a user interface (UI), the UI comprising a first UI element for presenting at least a portion of the data entries and a second UI element for receiving user input associated with at least the portion of the data entries; and
receive, via the second UI element, first user input selecting the operation of interest in at least one data entry of the first plurality of data entries.

14. The system of claim 13, wherein the processing device is further configured to:
present, via the first UI element, the first subset of data entries;
receive, via a third UI element of the UI, second user input selecting one or more data entries of the first subset of data entries; and
remove the selected one or more data entries from the first subset of data entries.

15. The system of claim 12, wherein the processing device is further configured to:
generate one or more charts comprising information for the operation of interest on a first axis and information for the metrology data on a second axis from the updated first subset of data entries.

16. The system of claim 12, wherein the processing device is further configured to:
determine one or more third data entries of the first plurality of data entries that lack the operation of interest;
generate a virtual operation for the one or more third data entries based on a combination of two or more existing operations in the one or more third data entries, wherein the virtual operation corresponds to the operation of interest; and
generate a virtual sensor measurement for the virtual operation based on applying a weighted average of one or more sensor measurements associated with the two or more existing operations.

17. A non-transitory machine-readable storage medium storing instructions which, when executed, cause a processing device to perform operations comprising:
obtaining a first plurality of data entries comprising process data of one or more processes performed on a plurality of substrates, wherein each data entry of the first plurality of data entries comprises process data for a plurality of operations of the one or more processes, wherein one or more first data entries of the first plurality of data entries has at least one of a different operation mapping or different operation names than one or more second data entries of the first plurality of data entries;
determining an operation of interest from the first plurality of data entries, wherein for the one or more first data entries the operation of interest has at least a first operation mapping in the one or more processes or a first operation name, and wherein for the one or more second data entries the operation of interest has at least one of a second operation mapping in the one or more processes or a second operation name;
updating at least a first subset of data entries of the first plurality of data entries by normalizing the operation of interest across the first plurality of data entries;
labeling at least the first subset of data entries with a common label associated with the normalized operation of interest;
obtaining a second plurality of data entries comprising metrology data of the plurality of substrates;
linking the process data of the updated first subset of data entries of the first plurality of data entries to the metrology data of the second plurality of data entries; and
preparing the updated first subset of data entries for one or more data analysis operations based at least in part on the common label.

18. The non-transitory machine-readable storage medium of claim 17, wherein to determine the operation of interest, the processing device is to perform operations comprising:
providing a user interface (UI), the UI comprising a first UI element for presenting at least a portion of the data entries and a second UI element for receiving user input associated with at least the portion of the data entries; and
receiving, via the second UI element, first user input selecting the operation of interest in at least one data entry of the first plurality of data entries.

19. The non-transitory machine-readable storage medium of claim 18, wherein the processing device is to perform operations further comprising:
presenting, via the first UI element, the first subset of data entries;
receiving, via a third UI element of the UI, second user input selecting one or more data entries of the first subset of data entries; and
removing the selected one or more data entries from the first subset of data entries.

20. The non-transitory machine-readable storage medium of claim 17, wherein the processing device is to perform operations further comprising:
determining one or more third data entries of the first plurality of data entries that lack the operation of interest;
generating a virtual operation for the one or more third data entries based on a combination of two or more existing operations in the one or more third data entries, wherein the virtual operation corresponds to the operation of interest; and
generating a virtual sensor measurement for the virtual operation based on applying a weighted average of one or more sensor measurements associated with the two or more existing operations.
